(19) United States
(12) Patent Application Publication
(10) Pub. No.: US 2026/0259273 A1
(43) Pub. Date: Sep. 3, 2026

(54) VOLTAGE MEASUREMENT CIRCUIT

(71) Applicant: Nuvoton Technology Corporation Japan, Kyoto (JP)

(72) Inventors: Hitoshi KOBAYASHI, Kyoto (JP); Michiko YAMADA, Kyoto (JP); Sachiko SOGA, Kyoto (JP); Akihiro KAWAMURA, Kyoto (JP); Akihiro TAKATA, Kyoto (JP)

(21) Appl. No.: 19/560,991

(22) Filed: Mar. 9, 2026

Related U.S. Application Data
(63) Continuation of application No. PCT/JP2024/032357, filed on Sep. 10, 2024.

(30) Foreign Application Priority Data
Sep. 12, 2023 (JP) 2023-147983

(51) Int. Cl. G01R 31/385; G01R 31/30; G01R 31/396

(52) U.S. Cl. CPC G01R 31/385; G01R 31/30; G01R 31/396

(57) ABSTRACT

A voltage measurement circuit includes: a first switched capacitor filter connected to a first battery cell included in a cell pack; a second switched capacitor filter connected to a second battery cell included in the cell pack; and a first amplifier shared by the first switched capacitor filter and the second switched capacitor filter. The first switched capacitor filter includes: a first switch group; a first capacitor; and a third switch group, the second switched capacitor filter includes: a second switch group; and a second capacitor; and a fourth switch group, the first switch group is electrically isolated from the third switch group via the first capacitor, and the second switch group is electrically isolated from the fourth switch group via the second capacitor.

### CROSS REFERENCE TO RELATED APPLICATIONS

This is a continuation application of PCT International Patent Application No. PCT/JP2024/032357 filed on Sep. 10, 2024, designating the United States of America, which is based on and claims priority of Japanese Patent Application No. 2023-147983 filed on Sep. 12, 2023. The entire disclosures of the above-identified applications, including the specifications, drawings and claims are incorporated herein by reference in their entirety.

### FIELD

The present disclosure relates to a voltage measurement circuit, and in particular to a voltage measurement circuit for use in measuring the voltage of each of a plurality of battery cells connected in series and included in a cell pack.

### BACKGROUND

Lithium-ion batteries or lithium-ion capacitors are used in a variety of applications as rechargeable batteries with high energy density. In particular, electric vehicles, energy storage systems (ESS), and the like, which require large capacity, use lithium-ion batteries or lithium-ion capacitors as lithium-ion cell packs including a plurality of battery cells connected in series or in parallel.

Lithium-ion cell packs have the risk of deterioration due to overdischarge, and heat generation and explosion due to overcharge. For this reason, a battery management system that measures the output voltage of each battery cell and controls charging and discharging so that each battery cell does not overdischarge or overcharge is indispensable for lithium-ion cell packs. In addition, the battery management system requires highly accurate voltage measurement because the battery management system measures the output voltage of each battery cell and estimates the state of charge (SOC).

Therefore, conventionally, a technique of providing a voltage measurement circuit such as an analog-to-digital converter that enables the measurement of the output voltage of each battery cell in a cell pack has been proposed (for example, see Patent Literature (PTL) 1 and PTL 2).

In the technique of PTL 1, the individual battery cells connected in series in a cell pack are connected to a single analog-to-digital converter via a multiplexer that selects between positive and negative electrodes, and measurements are performed in turn by the single analog-to-digital converter while switching between the battery cells. Hereinafter, this scheme is referred to as “multiplexer scheme”. However, in the multiplexer scheme in PTL 1, the voltage measurement is performed by the single analog-to-digital converter while sequentially switching between the battery cells connected in series. Therefore, the period for measuring the voltages of all the battery cells increases.

On the other hand, in the technique of PTL 2, measurements are performed using a plurality of analog-to-digital converters each connected to a respective one of battery cells connected in series in a cell pack. Hereinafter, this scheme is referred to as “parallel scheme”. According to the parallel scheme described in PTL 2, the output voltage of each of battery cells connected in series in a cell pack can be measured simultaneously, which makes it possible to shorten the period for measuring the voltages of the battery cells.

Moreover, motors of electric vehicles are being downsized by increasing the gear ratio to allow the motor to operate at higher rotational speeds. The current flowing through the lithium-ion cell pack to which the motor is connected varies rapidly due to the high-speed rotation of the motor. Since the output voltage of each battery cell is the sum of (i) the voltage generated by the internal impedance of the battery cell and the current flowing through the cell pack and (ii) the open circuit voltage (OCV) of the battery cell, rapidly varying current causes the output voltage of each battery cell to vary rapidly.

From this point of view, the multiplexing scheme described in PTL 1 has a problem of increasing voltage measurement error due to the difference in measurement time between battery cells. Therefore, for lithium-ion cell packs that are connected to high-speed rotating motors, the parallel scheme described in PTL 2 that can simultaneously measure the output voltages of the battery cells may be used.

### CITATION LIST

### Patent Literature

PTL 1: WO 2019/044856

PTL 2: WO 2016/051684

### SUMMARY

### Technical Problem

However, the parallel scheme described in PTL 2 requires the same number of analog-to-digital converters as the number of battery cells to be measured. Therefore, the current consumption and the mounting area in a semiconductor device including these battery cells increase.

The problem of current consumption will be described in more detail. In a typical battery management system, a single semiconductor device that performs voltage measurement measures a cell voltage of each of battery cells connected in series in a range from 12 to 24 battery cells. Since the lithium-ion battery cell outputs a voltage of around 3.7 V, the total voltage of the 24 series-connected battery cells is around 90 V. In other words, a semiconductor device that manages a cell pack including 24 series-connected battery cells supplies power by using, as a power source, the target cell pack including the number of series-connected battery cells that the semiconductor device manages, and therefore the power supply voltage is 90 V.

On the other hand, the current consumption of a single delta-sigma analog-to-digital converter, which is often used in battery management systems, is approximately 0.5 mA to 1.0 mA. Therefore, the power consumption of the semiconductor device is approximately 1 W from the following equation.
0.5 mA×24 battery cells×90 V=1080 mW

For semiconductor devices, heat loss due to power consumption of 1 W is an amount that cannot be tolerated by heat dissipation only from printed circuit boards on which semiconductor devices are mounted, and special heat measures such as providing heat sinks are required.

In view of this, the present disclosure provides a voltage measurement circuit that operates at a higher speed than the conventional multiplexing scheme and is superior in current consumption and mounting area to a voltage measurement circuit of the conventional parallel scheme.

### Solution to Problem

To solve the above problem, a voltage measurement circuit according to one aspect of the present disclosure is a voltage measurement circuit for use in measuring a voltage of each of a plurality of battery cells connected in series and included in a cell pack, the voltage measurement circuit includes: a first switched capacitor filter including an input terminal connected to a first battery cell among the plurality of battery cells included in the cell pack; a second switched capacitor filter including an input terminal connected to the first battery cell or a second battery cell among the plurality of battery cells included in the cell pack; and a first amplifier including an input terminal connected to an output terminal of the first switched capacitor filter and an output terminal of the second switched capacitor filter. The first switched capacitor filter includes: a first switch group including an input terminal connected to the first battery cell; and a first capacitor connected to an output terminal of the first switch group, the second switched capacitor filter includes: a second switch group including an input terminal connected to the first battery cell or the second battery cell; and a second capacitor connected to an output terminal of the second switch group, and the first switch group is electrically isolated from the first amplifier via the first capacitor, and the second switch group is electrically isolated from the first amplifier via the second capacitor.

### Advantageous Effects

The present disclosure provides a voltage measurement circuit that operates at a higher speed than the conventional multiplexing scheme and is superior in current consumption and mounting area than the conventional parallel scheme.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a circuit block diagram illustrating a schematic configuration of a main portion of a voltage measurement circuit according to an embodiment.

FIG. 2A is a circuit diagram illustrating a detailed configuration of the amplifier-sharing analog-to-digital converter illustrated in FIG. 1.

FIG. 2B is a timing chart of the clock signals shown in FIG. 2A.

FIG. 3 is a block diagram illustrating an overall configuration of the voltage measurement circuit according to the embodiment.

FIG. 4 is a circuit block diagram illustrating a schematic configuration of a main portion of a voltage measurement circuit according to Variation 1 of the embodiment.

FIG. 5 is a circuit block diagram illustrating a schematic configuration of a main portion of a voltage measurement circuit according to Variation 2 of the embodiment.

FIG. 6 is a circuit diagram of an amplifier-sharing analog-to-digital converter that constitutes a voltage measurement circuit according to Variation 3 of the embodiment.

FIG. 7A is a circuit diagram of an amplifier-sharing analog-to-digital converter that constitutes a voltage measurement circuit according to Variation 4 the embodiment.

FIG. 7B is a timing chart of the clock signals shown in FIG. 7A.

FIG. 8A is a circuit diagram of an amplifier-sharing analog-to-digital converter that constitutes a voltage measurement circuit according to Variation 5 the embodiment.

FIG. 8B is an example of the timing chart of the clock signals shown in FIG. 8A.

FIG. 8C is another example of the timing chart of the clock signals shown in FIG. 8A.

### DESCRIPTION OF EMBODIMENT

In the following, one or more embodiments of the present disclosure will be described in detail with reference to drawings. Note that each of the one or more embodiments described below is a specific example of the present disclosure. The numerical values, circuits, circuit components, connection of the circuit components, signals, timing and waveforms of the signals, etc. described in the following one or more embodiments are given merely by way of illustration and are not intended to limit the present disclosure. Moreover, each figure is not necessarily a precise depiction. In the figures, circuit components that are essentially have the same functions and of the same type share like reference signs and overlapping description is omitted or simplified. Moreover, language such as “A and B are connected” means that A and B are electrically connected, not only when A and B are directly connected, but also when A and B are indirectly connected with one or more other circuit elements interposed between A and B.

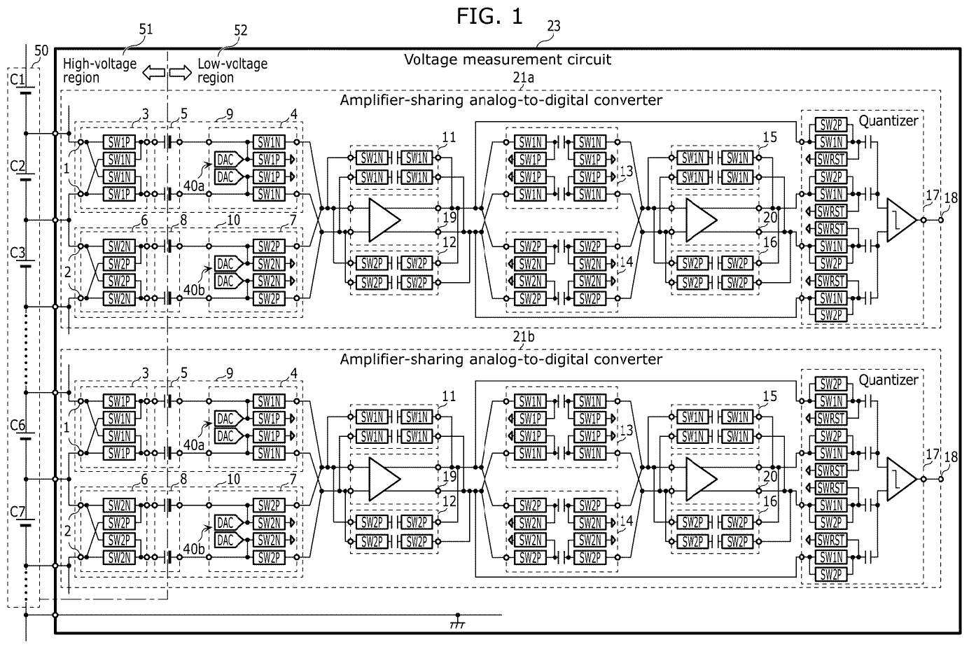

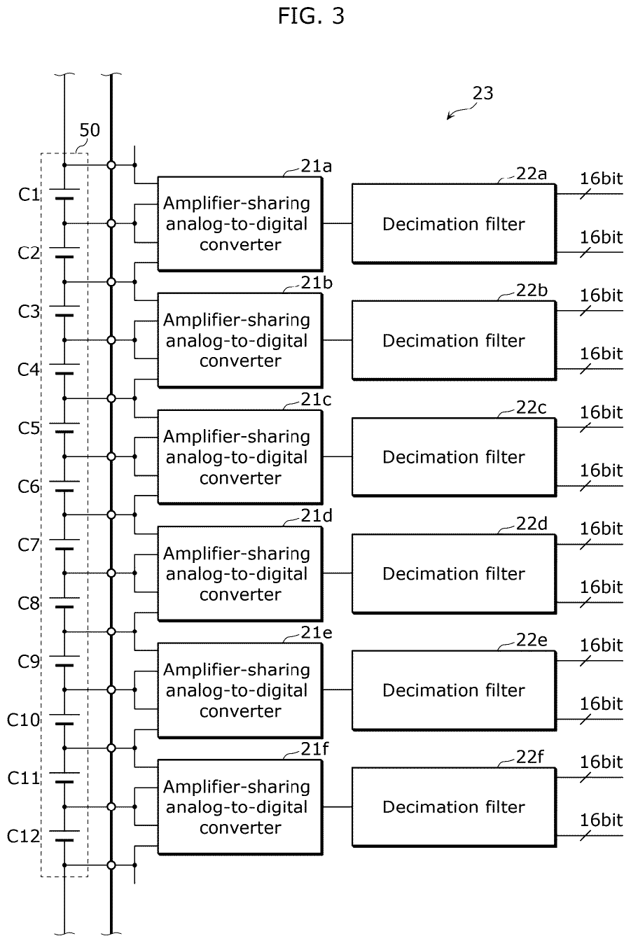

FIG. 1 is a circuit block diagram illustrating a schematic configuration of the main portion of voltage measurement circuit 23 according to an embodiment. This figure illustrates amplifier-sharing analog-to-digital converter 21a that measures a voltage of battery cell C2 and a voltage of battery cell C3, which are included in cell pack 50, and amplifier-sharing analog-to-digital converter 21b that measures a voltage of battery cell C6 and a voltage of battery cell C7, which are included in cell pack 50. Note that voltage measurement circuit 23 is a semiconductor device implemented as a single integrated circuit, and may include not only these two amplifier-sharing analog-to-digital converters 21a and 21b, but also the number of amplifier-sharing analog-to-digital converters sufficient to measure voltages of all the battery cells included in cell pack 50. Moreover, FIG. 1 illustrates the main portion of voltage measurement circuit 23, and the overall configuration and more detailed configuration of voltage measurement circuit 23 will be described later with reference to FIG. 3.

Cell pack 50 is a cell pack including a plurality of battery cells, such as C1 to C7, connected in series, and is, for example, a cell pack including 24 series-connected battery cells. Battery cells C1 to C7 and so on are, for example, lithium-ion battery cells.

Amplifier-sharing analog-to-digital converter 21a is a second-order delta-sigma modulator that modulates each of voltages of the two battery cells C2 and C3 to a pulse density. Amplifier-sharing analog-to-digital converter 21a includes first switched capacitor filter 9, second switched capacitor filter 10, third switched capacitor filter 11, fourth switched capacitor filter 12, fifth switched capacitor filter 13, sixth switched capacitor filter 14, seventh switched capacitor filter 15, eighth switched capacitor filter 16, first amplifier 19, second amplifier 20, and quantizer 17.

Among these elements, first switched capacitor filter 9, third switched capacitor filter 11, fifth switched capacitor filter 13, and seventh switched capacitor filter 15 are circuit components dedicated to digitizing a voltage of battery cell C2. Second switched capacitor filter 10, fourth switched capacitor filter 12, sixth switched capacitor filter 14, and eighth switched capacitor filter 16 are circuit components dedicated to digitizing a voltage of battery cell C3. First amplifier 19, second amplifier 20, and quantizer 17 are circuit components shared in a time-division manner to digitize voltages of battery cells C2 and C3.

First switched capacitor filter 9 is a circuit that samples a voltage of first battery cell C2 (i.e., accumulates charge in a capacitor) and includes: first switch group 3 that includes first input terminal 1 connected across first battery cell C2 and turns on and off by connecting input terminal 1 to first battery cell C2; third switch group 4 that turns on and off by connecting its output terminal to the input terminal of first amplifier 19; and first capacitor 5 that is connected between the output terminal of first switch group 3 and the input terminal of third switch group 4, which is connected between the output terminal of first switch group 3 and the input terminal of third switch group 4. Note that, the term “input terminal” means, on an input side of each circuit, both (i) a terminal connected to a high-potential line that is a signal line for transmitting a voltage of a high-potential terminal of a battery cell, and (ii) a terminal connected to a low-potential line that is a signal line for transmitting a voltage of a low-potential terminal of the battery cell. Similarly, the term “output terminal” means, on an output side of each circuit, both (i) a terminal connected to the high-potential line of the battery cell, and (ii) a terminal connected to the low-potential line of the battery cell.

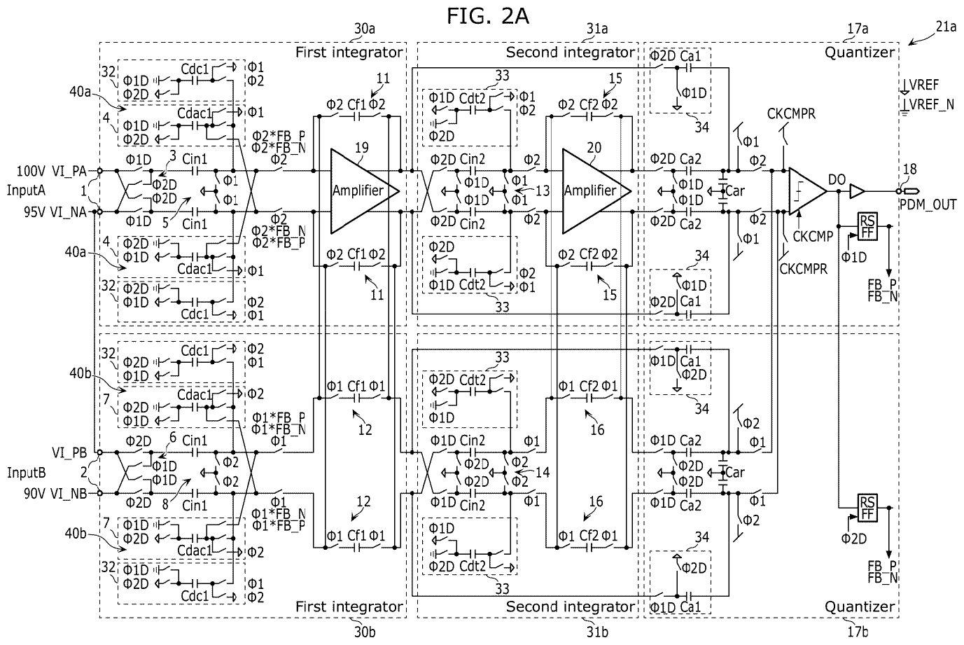

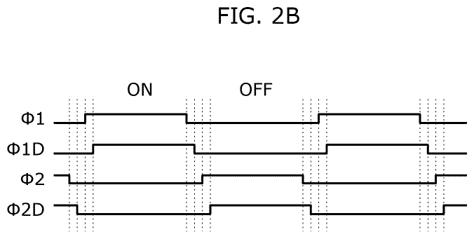

First switch group 3 includes: two switch elements SW1P that respectively turn on (i.e., connect) the high-potential line and the low-potential line of first battery cell C2 during a first period; and two switch elements SW1N that respectively turn on (i.e., connect) the high-potential line and the low-potential line of first battery cell C2 in a crossed manner during a second period. Note that the first period and the second period will be described in detail with reference to FIG. 2B.

Third switch group 4 includes: first digital-to-analog converter 40a that performs digital-to-analog conversion by using an output of quantizer 17 as an input and outputs the resulting analog voltage to the input terminal of third switch group 4; two switch elements SW1N that respectively turn on (i.e., connect) the high-potential line and low-potential line of first battery cell C2 during the second period; and two switch elements SW1P that connects the high-potential line and the low-potential line of first battery cell C2 to a reference voltage during the first period. Note that third switch group 4 is not an essential element included in first switched capacitor filter 9 when an output of quantizer 17 will not be fed back, for example.

Note that in each of the reference signs of switch elements (such as “SW1P”), the numeral following “SW” indicates the battery cell to be measured. The numeral “1” denotes first battery cell C2 and the numeral “2” denotes second battery cell C3. The letter following the numeral indicates the period during which the switch element is turned on (i.e., connected). The letter “P” denotes the first period and the letter “N” denotes the second period. Each switch element is, for example, a metal-oxide-semiconductor field-effect transistor (MOSFET).

Second switched capacitor filter 10 is a circuit that samples a voltage of second battery cell C3 (i.e., accumulates charge in a capacitor) and includes: second switch group 6 that includes second input terminal 2 connected across second battery cell C3 and turns on and off by connecting second input terminal 2 to second battery cell C3; fourth switch group 7 that turns on and off by connecting its output terminal to the input terminal of first amplifier 19; and second capacitor 8 that is connected between the output terminal of second switch group 6 and the input terminal of fourth switch group 7.

Second switch group 6 includes: two switch elements SW2N that respectively turn on (i.e., connect) the high-potential line and the low-potential line of second battery cell C3 during the second period; and two switch elements SW2P that respectively turn on (i.e., connect) the high-potential line and the low-potential line of second battery cell C3 in a crossed manner during the first period.

Fourth switch group 7 includes: second digital-to-analog converter 40b that performs digital-to-analog conversion by using an output of quantizer 17 as an input and outputs the resulting analog voltage to the input terminal of fourth switch group 7; two switch elements SW2N that respectively turn on (i.e., connect) the high-potential line and low-potential line of second battery cell C3 during the second period; and two switch elements SW2P that connect the high-potential line and the low-potential line of second battery cell C3 to the reference voltage during the first period. Note that fourth switch group 7 is not an essential element included in second switched capacitor filter 10 when the output of quantizer 17 is not fed back, for example.

First amplifier 19 is shared in a time-division manner for integration of charge accumulated in first switched capacitor filter 9 (more precisely, first capacitor 5) and charge accumulated in second switched capacitor filter 10 (more precisely, second capacitor 8).

Third switched capacitor filter 11 is connected between the input terminal and the output terminal of first amplifier 19, and used for integration of charge accumulated in first switched capacitor filter 9 (more precisely, first capacitor 5). Third switched capacitor filter 11 includes: a capacitor inserted in the high-potential line of first battery cell C2 and two switch elements SW1N that turn on during the second period; and a capacitor inserted in the low-potential line of first battery cell C2 and two switch elements SW1N that turn on during the second period.

Fourth switched capacitor filter 12 is connected between the input terminal and the output terminal of first amplifier 19, and used for integration of charge accumulated in second switched capacitor filter 10 (more precisely, second capacitor 8). Fourth switched capacitor filter 12 includes: a capacitor inserted in the high-potential line of second battery cell C3 and two switch elements SW2P that turn on during the first period; and a capacitor inserted in the low-potential line of second battery cell C3 and two switch elements SW2P that turn on during the first period.

Fifth switched capacitor filter 13 is a second-stage circuit that samples a voltage of first battery cell C2 (i.e., accumulates charge in one or more capacitors). Fifth switched capacitor filter 13 includes: a capacitor inserted in the high-potential line of first battery cell C2; two switch elements SW1P that connect both terminals of the capacitor to the reference voltage during the first period; and two switch elements SW1N that connect the capacitor so as to be inserted in the high-potential line during the second period. Fifth switched capacitor filter 13 also includes: a capacitor inserted in the low-potential line of first battery cell C2; two switch elements SW1P that connect both terminals of the capacitor to the reference voltage during the first period; and two switch elements SW1N that connects the capacitor so as to be inserted in the low-potential line during the second period.

Sixth switched capacitor filter 14 is a second-stage circuit that samples a voltage of second battery cell C3 (i.e., accumulates charge in one or more capacitors). Sixth switched capacitor filter 14 includes: a capacitor inserted in the high-potential line of second battery cell C3; two switch elements SW2N that connect both terminals of the capacitor to the reference voltage during the second period; and two switch elements SW2P that connect the capacitor so as to be inserted in the high-potential line during the first period. Sixth switched capacitor filter 14 also includes: a capacitor inserted in the low-potential line of second battery cell C3; two switch elements SW2N that connect both terminals of the capacitor to the reference voltage during the second period; and two switch elements SW2P that connect the capacitor so as to be inserted in the low-potential line during the first period.

Second amplifier 20 is an amplifier shared in a time-division manner for integration of charge accumulated in fifth switched capacitor filter 13 and integration of charge accumulated in sixth switched capacitor filter 14.

Seventh switched capacitor filter 15 is connected between the input terminal and the output terminal of second amplifier 20 and used for integration of charge accumulated in the capacitor of fifth switched capacitor filter 13. Seventh switched capacitor filter 15 includes: a capacitor inserted in the high-potential line of first battery cell C2 and two switch elements SW1N that turn on during the second period; and a capacitor inserted in the low-potential line of first battery cell C2 and two switch elements SW1N that turn on during the second period.

Eighth switched capacitor filter 16 is connected between the input terminal and the output terminal of second amplifier 20, and used for integration of charge accumulated in sixth switched capacitor filter 14. Eighth switched capacitor filter 16 includes: a capacitor inserted in the high-potential line of second battery cell C3 and two switch elements SW2P that turn on during the first period; and a capacitor inserted in the low-potential line of second battery cell C3 and two switch elements SW2P that turn on during the first period.

Quantizer 17 is a 1-bit analog-to-digital converter that is connected to the output terminals of first amplifier 19 and second amplifier 20; is shared in a time-division manner to quantize the voltages of first battery cell C2 and second battery cell C3; compares the voltage of the high-potential line with the voltage of the low-potential line of the output terminal of each of first amplifier 19 and second amplifier 20; and outputs the comparison result from output terminal 18. Quantizer 17 includes: capacitors each connected a corresponding one of the high-potential lines and the low-potential lines of the output terminals of first amplifier 19 and second amplifier 20; switch element SW1N, switch element SW2P, and reset switch element SWRST that are connected to each of the capacitors. Note that, in this example, quantizer 17 is connected to both the output terminals of first amplifier 19 and second amplifier 20, but should not be limited to this connection. Quantizer 17 only needs to be connected to the output terminal of at least second amplifier 20 among first amplifier 19 and second amplifier 20.

Here, in the amplifier-sharing analog-to-digital converter 21a configured as described above, as illustrated in FIG. 1, first switch group 3 and second switch group 6 are disposed in high-voltage region 51, which is a circuit region in which one or more circuits that operate with a first power supply voltage are disposed. Circuit stages at and downstream of third switch group 4, which constitute a back-side modulator for first switch group 3, and circuit stages at and downstream of fourth switch group 7, which constitute a back-side modulator for second switch group 6, are disposed in low-voltage region 52, which is a circuit region in which one or more circuits that operate with a second power supply voltage lower than the first power supply voltage are disposed. Here, the first power supply voltage is, for example, for first switch group 3, a power supply voltage referenced to the potential of the low-potential terminal of first battery cell C2, which serves as ground. For second switch group 6, the first power supply voltage is referenced to the potential of the low-potential terminal of second battery cell C3, which serves as ground. Moreover, for example, for the circuit stages at and downstream of third switch group 4, which constitute the back-side modulator for first switch group 3, and the circuit stages at and downstream of fourth switch group 7, which constitute the back-side modulator for second switch group 6, the second power supply voltage is a power supply voltage referenced to the potential of the low-potential terminal of cell pack 50, which serves as ground.

With such an electrically-isolated configuration, an amplifier-sharing level shifter is configured in which a common amplifier is used while level-shifting (i) an output voltage of a first battery cell from a voltage level of a cell pack to a GND level of an integrated circuit and (ii) an output voltage of a second battery cell from the voltage level of the cell pack to the GND level of the integrated circuit.

Note that amplifier-sharing analog-to-digital converter 21b illustrated in FIG. 1 is a second-order delta-sigma modulator that modulates each of voltages of the two battery cells C6 and C7 to a pulse density, and has the same configuration as amplifier-sharing analog-to-digital converter 21a.

FIG. 2A is a circuit diagram illustrating a detailed configuration of amplifier-sharing analog-to-digital converter 21a illustrated in FIG. 1. FIG. 2B is a timing chart of the clock signals (Φ1, Φ1D, Φ2, and Φ2D) shown in FIG. 2A.

Note that in FIG. 2A, input voltage Input A of 5 V is input to first input terminal 1, where a potential of low-potential terminal VI_NA of first battery cell C2 in FIG. 1 is set to 95 V and a potential of high-potential terminal VI_PA of first battery cell C2 is set to 100 V, whereas input voltage Input B of 5 V is input to second input terminal 2, where a potential of low-potential terminal VI_NB of second battery cell C3 in FIG. 1 is set to 90 V and a potential of high-potential terminal VI_PB of second battery cell C3 is set to 95 V.

Moreover, in FIG. 2A, the reference voltage and its reference potential are denoted by symbols shown at the right end of FIG. 2A (respectively, “VREF” and “VREF_N”).

Moreover, in FIG. 2A, the clock signals (Φ1, Φ1D, Φ2, and Φ2D) supplied to respective switch elements and other circuit elements are indicated adjacent to the corresponding elements. The timing of the clock signals (Φ1, Φ1D, Φ2, and Φ2D) is as illustrated in FIG. 2B, and the switching elements are turned on during high (Hi) periods. A period including a Hi period of clock signal Φ1 and a Hi period of its delayed clock signal Φ1D is defined as a “first period”. A period including a Hi period of clock signal Φ2 and a Hi period of its delayed clock signal Φ2D is defined as a “second period”.

In FIG. 2A, in amplifier-sharing analog-to-digital converter 21a, a first-stage integrator for voltage measurement of first battery cell C2 (i.e., Input A) is denoted as first integrator 30a, and a second-stage integrator for voltage measurement of first battery cell C2 is denoted as second integrator 31a. In contrast, a first-stage integrator for voltage measurement of second battery cell C3 (i.e., Input B) is denoted as first integrator 30b, and a second-stage integrator for voltage measurement of second battery cell C3 is denoted as second integrator 31b.

Note that first amplifier 19 in first integrator 30a is also shared with first integrator 30b. Similarly, second amplifier 20 in second integrator 31a is shared with second integrator 31b.

Here, FIG. 2A also illustrates an additional circuit configuration included in amplifier-sharing analog-to-digital converter 21a, which is not illustrated in FIG. 1. For example, two DC shift circuits 32 that constitute each of first integrators 30a and 30b are circuits that convert a battery cell voltage that takes only positive values (here, 0 V to 5 V) into a differential signal (for example, −2.5 V to 2.5 V) by subtracting a constant voltage (for example, 2.5 V) from the battery cell voltage. Moreover, two dither circuits 33 that constitute each of second integrators 31a and 31b are circuits for reducing an idle tone that occurs in principle in the delta-sigma modulator according to the present embodiment. Moreover, two feedforward paths 34 that constitute each of quantizers 17a and 17b are circuits including switch elements SW1N and SW2P, which are also illustrated in FIG. 1, and are feedforward paths of the Cascaded Integrator Feed-Forward (CIFF) type.

As can be seen from FIG. 2A and FIG. 2B, the main operation of amplifier-sharing analog-to-digital converter 21a illustrated in FIG. 2A is as follows.

For voltage measurement of first battery cell C2 (i.e., Input A), during the first period (during which clock signal Φ1 or Φ1D is Hi), a voltage of first battery cell C2 (i.e., Input A) is sampled by first switched capacitor filter 9 (more precisely, charge is accumulated in first capacitor 5). During the second period (during which clock signal Φ2 or Φ2D is Hi), a difference between the voltage sampled by first switched capacitor filter 9 and the voltage that is digital-to-analog converted based on an output of quantizer 17a is integrated by first integrator 30a.

Furthermore, during the next first period (during which clock signal Φ1 or Φ1D is Hi), the value integrated by first integrator 30a is sampled by fifth switched capacitor filter 13. During the next second period (during which clock signal Φ2 or Φ2D is Hi), a voltage sampled by fifth switched capacitor filter 13 is integrated by second integrator 31a and quantized by quantizer 17a.

In contrast, for voltage measurement of second battery cell C3 (i.e., Input B), during the second period (during which clock signal Φ2 or Φ2D is Hi), a voltage of second battery cell C3 (i.e., Input B) is sampled by second switched capacitor filter 10 (more precisely, charge is accumulated in second capacitor 8). During the first period (during which clock signal Φ1 or Φ1D is Hi), a difference between the voltage sampled by second switched capacitor filter 10 and a voltage that is digital-to-analog converted based on an output of quantizer 17b is integrated by first integrator 30b.

Furthermore, during the next second period (during which clock signal Φ2 or Φ2D is Hi), the value integrated by first integrator 30b is sampled by sixth switched capacitor filter 14. During the next first period (during which clock signal Φ1 or Φ1D is Hi), a voltage sampled by sixth switched capacitor filter 14 is integrated by second integrator 31b and quantized by quantizer 17b.

Note that amplifier-sharing analog-to-digital converter 21b illustrated in FIG. 1 also performs the same operation as amplifier-sharing analog-to-digital converter 21a illustrated in FIG. 2A.

Accordingly, in each of amplifier-sharing analog-to-digital converters 21a and 21 b, first amplifier 19, second amplifier 20, and quantizer 17 are shared in a time-division manner (i.e., used alternately) to digitize voltages of battery cells C2 and C3.

As a result, since voltage measurement circuit 23 according to the present embodiment multiplexes the voltage measurement in each of the two battery cells, voltage measurement circuit 23 can operate at a higher speed than the conventional multiplexer scheme that multiplexes the voltage measurements of all the battery cells. Furthermore, in voltage measurement circuit 23 according to the present embodiment, first switch group 3 is electrically isolated from the circuit stages at and downstream of third switch group 4, which constitute the back-side modulator for first switch group 3, via first capacitor 5, and second switch group 6 is electrically isolated from the circuit stages at and downstream of fourth switch group 7, which constitute the back-side modulator for second switch group 6, via second capacitor 8. In addition, voltage measurement circuit 23 shares first amplifier 19, second amplifier 20, and quantizer 17 for each voltage measurement of the two battery cells. Therefore, compared with the conventional parallel scheme, voltage measurement circuit 23 according to the present application is superior in terms of current consumption and mounting area.

In general, for a level shifter using a delta-sigma analog-to-digital converter or a switched-capacitor-filter integrator, the total current consumption is the sum of charge/discharge current consumption of switched capacitors and current consumption of amplifiers, and the current consumption of the amplifiers accounts for the major part of the sum. Therefore, the current consumption can be halved by sharing an amplifier between two circuits by using amplifier-sharing according to the present embodiment.

Since the voltage measurement circuit for a cell pack according to the conventional of parallel scheme uses the same number of analog-to-digital converters as the battery cells of the cell pack, halving the current consumption of the circuit by using an amplifier-sharing analog-to-digital converter or an amplifier-sharing level shifter as in the present embodiment eliminates the need for special heat dissipation measures in semiconductor devices.

In addition, a switched capacitor includes three elements: A switch, a capacitor, and an amplifier. Amplifier-sharing analog-to-digital converters and amplifier-sharing level shifters allow two voltage-measurement circuits to share a single common amplifier, thereby reducing the circuit area.

Moreover, an analog-to-digital converter used in a voltage measurement circuit of a cell pack is typically operated as an oversampling analog-to-digital converter. In amplifier-sharing analog-to-digital converters 21a and 21b according to the present disclosure, measurement timings of the first battery cell and the second battery cell are shifted by a half period with respect to an input sampling clock (i.e., a half period where the combined duration of clock signals Φ1 and Φ2 is defined as one period). However, the input sampling clock is much faster than the output data rate. When a 256-times oversampling delta-sigma analog-to-digital converter is operated at an output rate of 10 Ksps (sample per second), an input sampling frequency is 2.56 MHz, and the half-period offset corresponds to a time that is negligible with respect to measurement simultaneity.

Therefore, in a voltage measurement circuit for a cell pack employing the parallel scheme, use of amplifier-sharing analog-to-digital converters 21a and 21b according to the present disclosure, each serving as both an amplifier-sharing analog-to-digital converter and an amplifier-sharing level shifter, is effective in terms of power consumption, circuit area, and functional safety.

FIG. 3 is a block diagram illustrating an overall configuration of voltage measurement circuit 23 according to the embodiment. The figure illustrates a block configuration of voltage measurement circuit 23 that includes a delta-sigma analog-to-digital converter including six amplifier-sharing analog-to-digital converters 21a to 21f and six decimation filters 22a to 22f, which are required to measure voltages of all battery cells C1 to C12 included in cell pack 50 in parallel.

Each of the six amplifier-sharing analog-to-digital converters 21a to 21f has the same configuration as amplifier-sharing analog-to-digital converter 21a illustrated in FIG. 1 and FIG. 2A.

Each of the six decimation filters 22a to 22f performs averaging processing on the 1-bit high-speed stream output from a corresponding one of amplifier-sharing analog-to-digital converters 21a to 21f, and outputs two 16-bit signals indicating the respective voltages of the two battery cells.

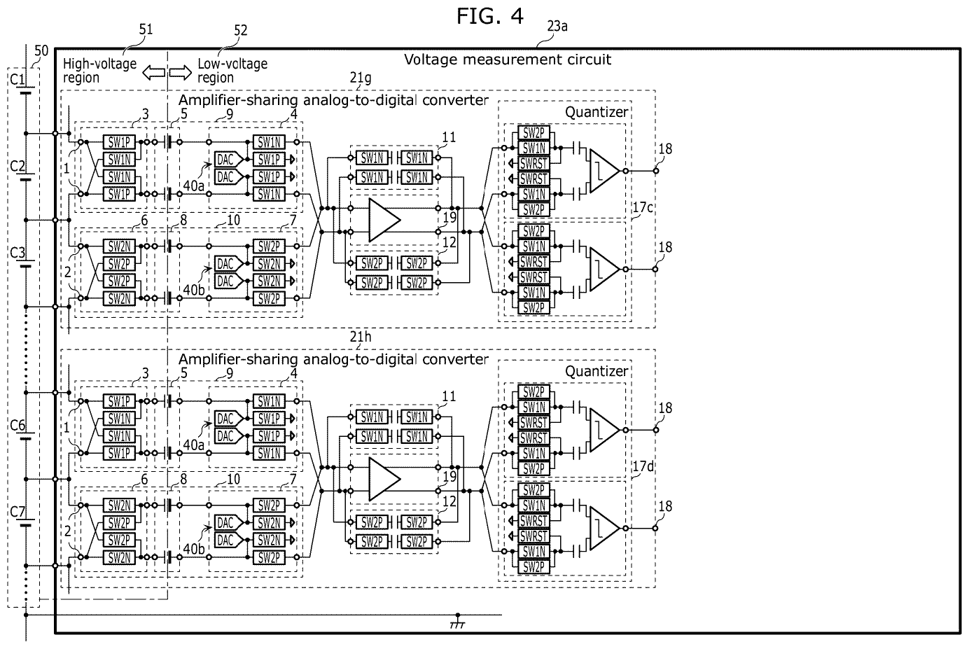

FIG. 4 is a circuit block diagram illustrating a schematic configuration of the main portion of voltage measurement circuit 23a according to Variation 1 of the embodiment. The figure illustrates amplifier-sharing analog-to-digital converter 21g that measures a voltage of battery cell C2 and a voltage of battery cell C3, and amplifier-sharing analog-to-digital converter 21h that measures a voltage of battery cell C6 and a voltage of battery cell C7. Battery cells C2, C3, C6, and C7 are included in cell pack 50.

Amplifier-sharing analog-to-digital converters 21g and 21h according to the present variation each constitute a first-order delta-sigma modulator, and thus are different from amplifier-sharing analog-to-digital converters 21a and 21b according to the embodiment illustrated in FIG. 1, which each constitute a second-order delta-sigma modulator. Moreover, amplifier-sharing analog-to-digital converters 21g and 21h according to the present variation respectively include quantizers 17c and 17d, each being 1.5-bit quantizers (i.e., producing three output levels), and thus are different from amplifier-sharing analog-to-digital converters 21a and 21b according to the embodiment, which each include a 1-bit quantizer.

Voltage measurement circuit 23a according to the present variation also has features similar to those of voltage measurement circuit 23 according to the embodiment. Accordingly, voltage measurement circuit 23a can operate at a higher speed than the conventional multiplexer scheme, and is superior in current consumption and mounting area to the conventional parallel scheme. Furthermore, voltage measurement circuit 23a can constitute a delta-sigma analog-to-digital converter having such features.

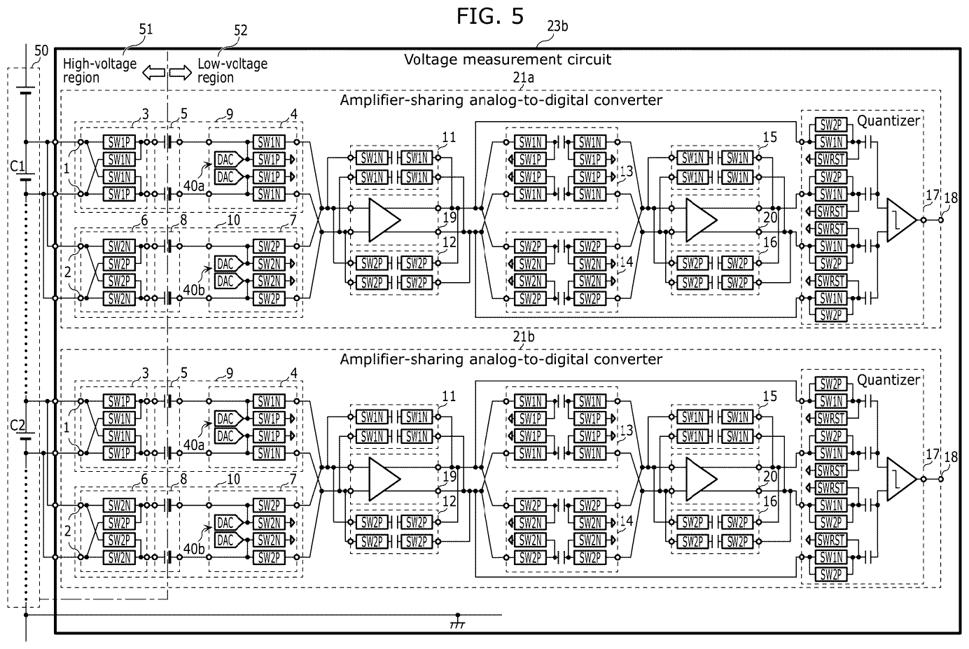

FIG. 5 is a circuit block diagram illustrating a schematic configuration of the main portion of voltage measurement circuit 23b according to Variation 2 of the embodiment. Voltage measurement circuit 23b differs from voltage measurement circuit 23 according to the embodiment in that both first input terminal 1 and second input terminal 2 of each of amplifier-sharing analog-to-digital converters 21a and 21b according to the present variation are connected across the same battery cell, and measures the voltage using two redundant switched capacitor filter circuits. This improves failure resistance of voltage measurement circuit 23b.

In other words, in the embodiment, voltage measurement is performed for two vertically adjacent battery cells in a cell pack using a single amplifier-sharing analog-to-digital converter, whereas in the present variation, voltage measurement is performed for a single battery cell using a single amplifier-sharing analog-to-digital converter that is connected to the single battery cell via two input terminals. In a voltage measurement circuit for a cell pack, a redundant configuration may be employed in accordance with the functional safety requirements of ISO 26262. In the case of the amplifier-sharing analog-to-digital converter according to the present variation, an amplifier is shared and not fully redundant. However, the failure rate is higher, for example, in terminals of semiconductor devices, switches connected to the terminals, and capacitors connected via these switches. On the other hand, since the failure rate of an amplifier that may be a common cause of failure is low, a high safety integrity level (SIL) can be achieved even with such a configuration.

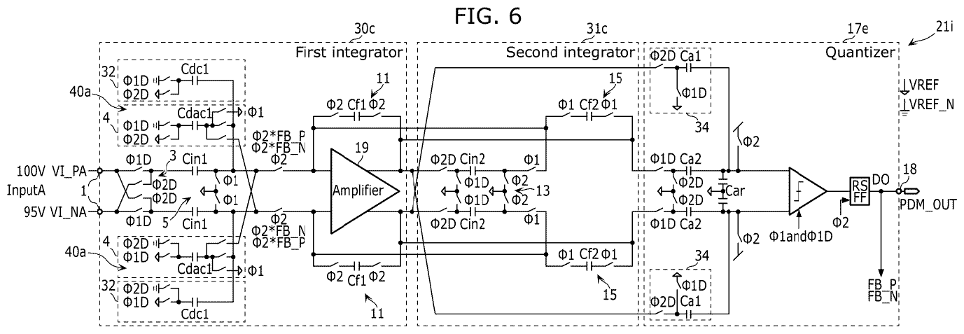

FIG. 6 is a circuit diagram of amplifier-sharing analog-to-digital converter 21i that constitutes a voltage measurement circuit according to Variation 3 of the embodiment. The figure illustrates a circuit configuration of amplifier-sharing analog-to-digital converter 21i, in which one amplifier is shared in a time-division manner by two integrators, which are a first-order integrator and a second-order integrator.

Amplifier-sharing analog-to-digital converter 21i according to the present variation constitutes a second-order delta-sigma modulator, and includes: first integrator 30c including an input terminal connected to a battery cell included in cell pack 50; second integrator 31c including an input terminal connected to the output terminal of first integrator 30c; and first amplifier 19 that is shared by first integrator 30c and second integrator 31c; and quantizer 17e including an input terminal connected to the output terminal of second integrator 31c; and first digital analog converter 40a using an output of quantizer 17e as an input and outputs a resulting analog voltage to the input terminal of first integrator 30c. First integrator 30c and second integrator 31c each integrate an input signal by sharing first amplifier 19 in a time-division manner.

Note that the following points are the same as amplifier-sharing analog-to-digital converter 21a according to the embodiment: first integrator 30c includes first switched capacitor filter 9; first switched capacitor filter 9 includes: first switch group 3 that turns on and off by connecting its input terminal to a battery cell, third switch group 4 that turns on and off by connecting its output terminal to the input terminal of an amplifier, and first capacitor 5 connected between the output terminal of first switch group 3 and the input terminal of third switch group 4; first switch group 3 is electrically isolated from first amplifier 19 via first capacitor 5; and first switch group 3 is disposed in high-voltage region 51 in which one or more circuits that operate with a first power supply voltage are disposed, and third switch group 4 and first amplifier 19 are disposed in low-voltage region 52 that is a circuit region in which one or more circuits that operate with a second power supply voltage lower than the first power supply voltage are disposed.

Therefore, in amplifier-sharing analog-to-digital converter 21i according to the present variation, first switch group 3 is electrically isolated from the circuit stages at and downstream of third switch group 4, which constitute the back-side modulator for first switch group 3, via first capacitor 5 (i.e., constituting a level shifter) and since first amplifier 19 is shared by two integrators, the current consumption and mounting area are superior to the conventional parallel scheme.

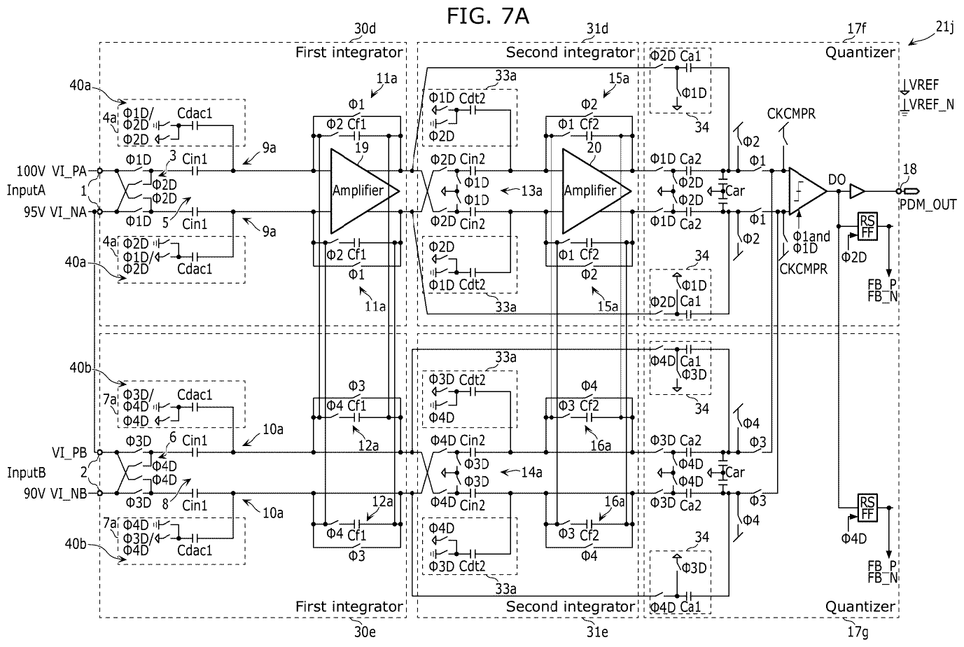

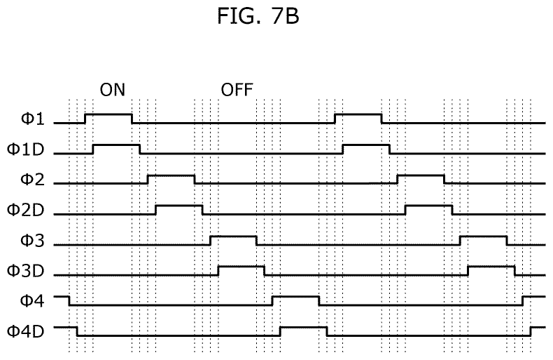

FIG. 7A is a circuit diagram of amplifier-sharing analog-to-digital converter 21j that constitutes the voltage measurement circuit according to Variation 4 of the embodiment. FIG. 7B is a timing chart of the clock signals shown in FIG. 7A.

Amplifier-sharing analog-to-digital converter 21j according to the present variation is substantially identical in configuration to amplifier-sharing analog-to-digital converter 21a according to the embodiment illustrated in FIG. 2A, but differs from the embodiment in that it operates when supplied with four sets of phase-shifted clock signals (Φ1 and Φ1D, Φ2 and Φ2D, Φ3 and Φ3D, and Φ4 and Φ4D), whereas amplifier-sharing analog-to-digital converter 21j according to the embodiment operates when supplied with two sets of phase-shifted clock signals (Φ1 and Φ1D, and Φ2 and Φ2D).

Amplifier-sharing analog-to-digital converter 21j includes first integrator 30d, second integrator 31d, and quantizer 17f for voltage measurement in first battery cell C2 (i.e., Input A), and includes first integrator 30e, second integrator 31e, and quantizer 17g for voltage measurement of second battery cell C3 (i.e., Input B).

First integrator 30d includes first switched capacitor filter 9a, third switched capacitor filter 11a, and first amplifier 19. First switched capacitor filter 9a includes: first switch group 3, third switch group 4a, and first capacitor 5. Third switched capacitor filter 11a is a switched capacitor filter with a reset (short circuit) function.

Second integrator 31d includes fifth switched capacitor filter 13a, seventh switched capacitor filter 15a, and second amplifier 20. Seventh switched capacitor filter 15a is a switched capacitor filter with a reset (short circuit) function.

First integrator 30e includes second switched capacitor filter 10a and fourth switched capacitor filter 12a. Second switched capacitor filter 10a includes: second switch group 6, fourth switch group 7a, and second capacitor 8. Fourth switched capacitor filter 12a is a switched capacitor filter with a reset (short circuit) function.

Second integrator 31e includes sixth switched capacitor filter 14a and eighth switched capacitor filter 16a. Eighth switched capacitor filter 16a is a switched capacitor filter with a reset (short circuit) function.

For voltage measurement of first battery cell C2 (i.e., Input A), during the first period (during which clock signal Φ1 or Φ1D is Hi), a voltage of first battery cell C2 (i.e., Input A) is sampled by first switched capacitor filter 9a (more precisely, charge is accumulated in first capacitor 5) and at the same time, the input and output terminals of first amplifier 19 are short-circuited and reset by third switched capacitor filter 11a. During the second period (during which clock signal Φ2 or Φ2D is Hi), a difference between the voltage sampled by first switched capacitor filter 9a and a voltage that is digital-to-analog converted based on an output of quantizer 17f is integrated by first integrator 30d.

Furthermore, during the next first period (during which clock signal Φ1 or Φ1D is Hi), the value integrated by first integrator 30d is sampled by fifth switched capacitor filter 13a and at the same time, the input and output terminals of second amplifier 20 are short-circuited and reset by seventh switched capacitor filter 15a. During the next second period (during which clock signal Φ2 or Φ2D is Hi), a voltage sampled by fifth switched capacitor filter 13a is integrated by second integrator 31d and quantized by quantizer 17f.

In contrast, for voltage measurement of second battery cell C3 (i.e., Input B), during a third period (during which clock signal Φ3 or Φ3D is Hi), a voltage of second battery cell C3 (i.e., Input B) is sampled by second switched capacitor filter 10a (more precisely, charge is accumulated in second capacitor 8) and at the same time, the input and output terminals of first amplifier 19 are short-circuited and reset by fourth switched capacitor filter 12a. During the fourth period (during which clock signal Φ4 or Φ4D is Hi), a difference between the voltage sampled by second switched capacitor filter 10a and a voltage that is digital-to-analog converted based on an output of quantizer 17g is integrated by first integrator 30e.

Furthermore, during the next third period (during which clock signal Φ3 or Φ3D is Hi), the value integrated by first integrator 30e is sampled by sixth switched capacitor filter 14a and at the same time, the input and output terminals of second amplifier 20 are short-circuited and reset by eighth switched capacitor filter 16a. During the next fourth period (clock signal Φ4 or Φ4D is Hi), a voltage sampled by sixth switched capacitor filter 14a is integrated by second integrator 31e and quantized by quantizer 17g.

As described above, in amplifier-sharing analog-to-digital converter 21j according to the present variation, integration and reset are alternately performed for first amplifier 19 and second amplifier 20, thereby suppressing the occurrence of offset.

Furthermore, in amplifier-sharing analog-to-digital converter 21j according to the present variation, first amplifier 19, second amplifier 20, and quantizer 17 are shared in a time-division manner (i.e., used alternately) to digitize voltages of battery cells C2 and C3, as with analog-to-digital converter 21a according to the embodiment.

As a result, according to the voltage measurement circuit including amplifier-sharing analog-to-digital converter 21j, the voltage measurement is multiplexed for each pair of battery cells, and thus it can operate at a higher speed than the conventional multiplexer scheme in which voltage measurement of all the battery cells is multiplexed. Furthermore, in a voltage measurement circuit including amplifier-sharing analog-to-digital converter 21j, first switch group 3 is electrically isolated from the circuit stages at and downstream of third switch group 4, which constitute the back-side modulator for first switch group 3, via first capacitor 5, second switch group 6 is electrically isolated from the circuit stages at and downstream of fourth switch group 7, which constitute the back-side modulator for second switch group 6, via second capacitor 8, and first switch group 3 and third switch group 4 share first amplifier 19, second amplifier 20, and quantizer 17 for voltage measurement of each pair of battery cells, and thus the voltage measurement circuit including amplifier-sharing analog-to-digital converter 21j is superior in current consumption and mounting area to the conventional parallel scheme.

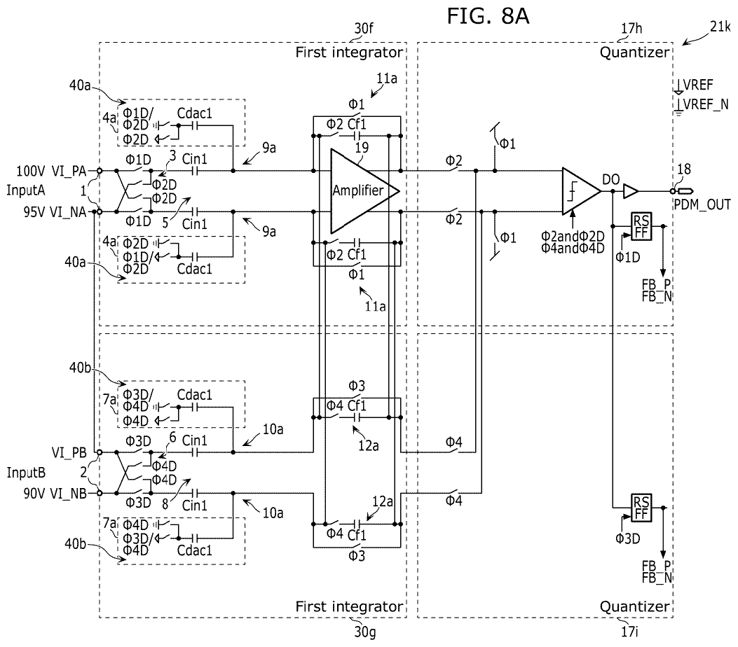

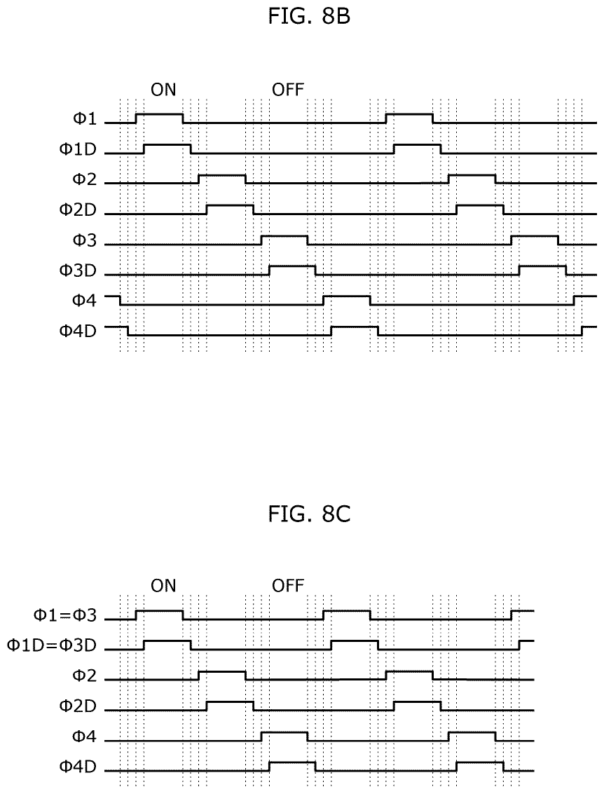

FIG. 8A is a circuit diagram of amplifier-sharing analog-to-digital converter 21k that constitutes the voltage measurement circuit according to Variation 5 of the embodiment. FIG. 8B is an example of the timing chart of the clock signals shown in FIG. 8A. FIG. 8C is another example of the timing chart of the clock signals shown in FIG. 8A.

Amplifier-sharing analog-to-digital converter 21k according to the present variation includes first integrator 30f and quantizer 17h for voltage measurement in first battery cell C2 (i.e., Input A), and includes first integrator 30g and quantizer 17i for voltage measurement of second battery cell C3 (i.e., Input B).

Amplifier-sharing analog-to-digital converters 21k according to the present variation is similar to amplifier-sharing analog-to-digital converter 21j according to Variation 4 illustrated in FIG. 7A in that amplifier-sharing analog-to-digital converters 21k operates when supplied with four sets of phase-shifted clock signals, but differs from analog-to-digital converter 21j according to Variation 4 in that amplifier-sharing analog-to-digital converters 21k constitutes a first-order delta-sigma modulator, whereas analog-to-digital converter 21j according to Variation 4 constitutes a second-order delta-sigma modulator.

Note that the timing of the clock signals illustrated in FIG. 8B is the same as the timing according to Variation 4 illustrated in FIG. 7B.

In contrast, the timing of the clock signals illustrated in FIG. 8C is unique to this variation. As shown in this figure, clock signals Φ1 and Φ1D also serve as clock signals Φ3 and Φ3D, respectively (i.e., they are identical).

Therefore, according to the timing illustrated in FIG. 8C, unlike the timing illustrated in FIG. 8B, the following operations proceed concurrently: (1) during the first period (during which clock signal Φ1 or Φ1D is Hi), a voltage of first battery cell C2 (i.e., Input A) is sampled by first switched capacitor filter 9a (more precisely, electric charge is accumulated in first capacitor 5), and at the same time, the input and output terminals of first amplifier 19 are short-circuited to reset first amplifier 19; and (2) during the third period (during which clock signal Φ3 or Φ3D is Hi), a voltage of second battery cell C3 (i.e., Input B) is sampled by second switched capacitor filter 10a (more precisely, electric charge is accumulated in second capacitor 8), and at the same time, the input and output terminals of first amplifier 19 are short-circuited to reset first amplifier 19.

As described above, according to the timing illustrated in FIG. 8C, integration and reset of first amplifier 19 and second amplifier 20 are performed by substantially three sets of phase-shifted clock signals, and therefore analog-to-digital conversion is performed at a higher speed than with the timing illustrated in FIG. 8B, in which integration and reset of first amplifier 19 and second amplifier 20 are performed by four sets of phase-shifted clock signals.

Furthermore, also in amplifier-sharing analog-to-digital converter 21k according to the present variation, first amplifier 19 and quantizer 17 are shared in a time-division manner (i.e., used alternately) to digitize voltages of battery cells C2 and C3, as with analog-to-digital converter 21j according to Variation 4.

As a result, according to the voltage measurement circuit including amplifier-sharing analog-to-digital converter 21k, the voltage measurement is multiplexed for each pair of battery cells, and thus it can operate at a higher speed than the conventional multiplexer scheme in which voltage measurement of all the battery cells is multiplexed. Furthermore, in a voltage measurement circuit including analog-to-digital converter 21k according to the present variation, first switch group 3 is electrically isolated from circuit stages at and downstream of third switch group 4, which constitute the back-side modulator for first switch group 3, via first capacitor 5 and second switch group 6 is electrically isolated from the circuit stages at and downstream of fourth switch group 7, constitute the back-side modulator for second switch group 6, via second capacitor 8, and first switch group 3 and second switch group 6 share first amplifier 19 and quantizer 17 for each voltage measurement of the pair of battery cells. Therefore, compared with the conventional parallel scheme, the voltage measurement circuit including amplifier-sharing analog-to-digital converter 21k according to the present variation is superior in terms of current consumption and mounting area.

As described above, voltage measurement circuit 23 according to the present embodiment is a voltage measurement circuit for use in measuring a voltage of each of a plurality of battery cells C1 to C3, etc. connected in series and included in cell pack 50, the voltage measurement circuit includes: first switched capacitor filter 9 including an input terminal connected to first battery cell C2 among the plurality of battery cells included in cell pack 50; second switched capacitor filter 10 including an input terminal connected to first battery cell C2 or second battery cell C3 among the plurality of battery cells included in cell pack 50; and first amplifier 19 including an input terminal connected to an output terminal of first switched capacitor filter 9 and an output terminal of second switched capacitor filter 10. First switched capacitor filter 9 includes: first switch group 3 including an input terminal connected to first battery cell C2; and first capacitor 5 connected to an output terminal of first switch group 3, the second switched capacitor 10 filter includes: second switch group 6 including an input terminal connected to first battery cell C2 or second battery cell C3; and second capacitor 8 connected to an output terminal of second switch group 6, and first switch group 3 is electrically isolated from first amplifier 19 via first capacitor 5, and second switch group 6 is electrically isolated from first amplifier 19 via second capacitor 8.

As a result, the voltage measurement is multiplexed for each pair of battery cells, and thus voltage measurement circuit 23 according to the present embodiment can operate at a higher speed than the conventional multiplexer scheme in which voltage measurement of all the battery cells is multiplexed. Furthermore, in voltage measurement circuit 23 according to the present embodiment, first switch group 3 is electrically isolated from the circuit stages at and downstream of first amplifier 19, which constitute the back-side modulator for first switch group 3, via first capacitor 5 and second switch group 6 is electrically isolated from the circuit stages at and downstream of first amplifier 19, which constitute the back-side modulator for second switch group 6, via second capacitor 8, and share first amplifier 19 for each voltage measurement of the pair of battery cells. Therefore, compared with the conventional parallel scheme, voltage measurement circuit 23 of the present embodiment is superior in terms of current consumption and mounting area.

In other words, according to voltage measurement circuit 23 according to the present embodiment, by employing amplifier-sharing analog-to-digital converters in a semiconductor device according to the parallel scheme in which measurement is performed by a plurality of analog-to-digital converters each connected to a respective one of battery cells connected in series in a cell pack, it possible to reduce the current consumption and circuit area of the plurality of analog-to-digital converters and to provide a voltage measurement circuit for a cell pack that is capable of measuring the battery cell voltages of the cell pack at substantially the same time.

Here, first switched capacitor filter 9 further includes third switch group 4 connected between first capacitor 5 and the input terminal of first amplifier 19; and second switched capacitor filter 10 further includes fourth switch group 7 connected between second capacitor 8 and the input terminal of first amplifier 19.

Moreover, first switch group 3 and second switch group 6 may be disposed in high-voltage region 51, high-voltage region 51 being a circuit region in which a circuit that operates with a first power supply voltage is disposed, and third switch group 4, fourth switch group 7, and first amplifier 19 may be disposed in low-voltage region 52, low-voltage region 52 being a circuit region in which a circuit that operates with a second power supply voltage lower than the first power supply voltage is disposed. With this, an amplifier-sharing level shifter is configured, and it is possible to suppress current consumption and heat loss.

Moreover, voltage measurement circuit 23 may further include third switched capacitor filter 11 and fourth switched capacitor filter 12 that are connected between the input terminal and an output terminal of first amplifier 19. With this, integration can be performed by first amplifier 19.

Moreover, voltage measurement circuit 23 may further include: quantizer 17 connected to a back-side modulator for first amplifier 19. Voltage measurement circuit 23, etc. may include an analog-to-digital converter that converts a voltage of first battery cell C2 into a digital value, or converts the voltage of first battery cell C2 and a voltage of second battery cell C3 into digital values in a time-division manner. With this, an analog-to-digital converter that operates at a higher speed and is superior in current consumption and mounting area than the conventional schemes is achieved.

Moreover, third switch group 4 may include a first digital-to-analog converter 40a that performs digital-to-analog conversion using an output of quantizer 17 as an input and output a resulting analog voltage to an input terminal of third switch group 4, fourth switch group 7 may include a second digital-to-analog converter 40b that performs digital-to-analog conversion using an output of quantizer 17 as an input and output a resulting analog voltage to an input terminal of fourth switch group 7, and voltage measurement circuit 23, etc. may include a delta-sigma analog-to-digital converter. With this, a delta-sigma analog-to-digital converter that operates at a higher speed and is superior in current consumption and mounting area than the conventional schemes is achieved.

Moreover, voltage measurement circuit 23 may further include, in a path between first amplifier 19 and quantizer 17: fifth switched capacitor filter 13 and sixth switched capacitor filter 14 each including an input terminal connected to an output terminal of first amplifier 19; second amplifier 20 including an input terminal connected to an output terminal of fifth switched capacitor filter 13 and connected to an output terminal of sixth switched capacitor filter 14; and seventh switched capacitor filter 15 and an eighth switched capacitor filter 16 that are connected between the input terminal and an output terminal of second amplifier 20. Voltage measurement circuit 23 may include a second-order or higher delta-sigma analog-to-digital converter. With this, a second-order or higher analog-to-digital converter that operates at a higher speed and is superior in current consumption and mounting area than the conventional schemes is achieved.

Moreover, the input terminal of second switched capacitor filter 10 may be connected to second battery cell C3. With this, voltage measurement is performed by two redundant switched capacitor filter circuits, thereby achieving a voltage measurement circuit satisfying a high safety level.

Moreover, a voltage measurement circuit for use in measuring a voltage of each of a plurality of battery cells C1 to C3, etc. connected in series and included in cell pack 50, the voltage measurement circuit includes: first integrator 30c including an input terminal connected to a battery cell included in cell pack 50; second integrator 31c including an input terminal connected to an output terminal of first integrator 30c; first amplifier 19 shared by first integrator 30c and second integrator 31c; quantizer 17e including an input terminal connected at least to an output terminal of second integrator 31c among first integrator 30c and second integrator 31c; and a first digital-to-analog converter 40a that performs digital-to-analog conversion using an output of quantizer 17e as an input and outputs a resulting analog voltage to the input terminal of first integrator 30c. First integrator 30c and second integrator 31c each integrate an input signal by sharing first amplifier 19 in a time-division manner, and the voltage measurement circuit may include a second-order or higher delta-sigma analog-to-digital converter.

With this, since first amplifier 19 is shared by two integrators, a voltage measurement circuit that is superior in consumption current and mounting area than the conventional parallel scheme is achieved.

Here, first integrator 30c may include first switched capacitor filter 9, first switched capacitor filter 9 may include: first switch group 3 including an input terminal connected to the battery cell; and first capacitor 5 connected to an output terminal of first switch group 3, and first switch group 3 may be electrically isolated from first amplifier 19 via first capacitor 5. With this, first switch group 3 is electrically isolated from the circuit stages at and downstream of first amplifier 19, which constitute the back-side modulator for first switch group 3, via first capacitor 5, thereby achieving a voltage measurement circuit in which current consumption is suppressed.

Note that first switched capacitor filter 9 may further include third switch group 4 connected between first capacitor 5 and the input terminal of first amplifier 19.

Moreover, first switch group 3 may be disposed in high-voltage region 51, and third switch group 4 and first amplifier 19 may be disposed in low-voltage region 52, high-voltage region 51 being a circuit region in which a circuit that operates with a first power supply voltage is disposed, low-voltage region 52 being a circuit region in which a circuit that operates with a second power supply voltage lower than the first power supply voltage is disposed. With this, an amplifier-sharing level shifter is configured, and it is possible to suppress current consumption and heat loss.

Hereinbefore, the voltage measurement circuit according to the present disclosure have been described based on the embodiment and variations, but the present disclosure should not be construed to be limited to the embodiment and variations. The scope of the present disclosure may encompass embodiments as a result of making, to the present embodiment and variations, various modifications that may be conceived by those skilled in the art, and different embodiments achieved by combining one or more elements in the embodiment and variations, as long as the resultant embodiments do not depart from the spirit of the present disclosure.

For example, in the above embodiment and so on, the amplifier-sharing analog-to-digital converter has been applied to a delta-sigma analog-to-digital converter. However, the amplifier-sharing analog-to-digital converter is not limited to this as application examples, and may be applied to a cyclic analog-to-digital converter or a successive-approximation analog-to-digital converter.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### Industrial Applicability

The voltage measurement circuit according to the present disclosure can be used as a voltage measurement circuit for use in measuring voltage of each of a plurality of battery cells connected in series in a cell pack, and in particular, as a voltage measurement circuit that operates at a higher speed than the conventional multiplexer scheme and is superior in current consumption and mounting area than the conventional parallel scheme.

1. A voltage measurement circuit for use in measuring a voltage of each of a plurality of battery cells connected in series and included in a cell pack, the voltage measurement circuit comprising:
a first switched capacitor filter including an input terminal connected to a first battery cell among the plurality of battery cells included in the cell pack;
a second switched capacitor filter including an input terminal connected to the first battery cell or a second battery cell among the plurality of battery cells included in the cell pack; and
a first amplifier including an input terminal connected to an output terminal of the first switched capacitor filter and an output terminal of the second switched capacitor filter, wherein
the first switched capacitor filter includes:
a first switch group including an input terminal connected to the first battery cell; and
a first capacitor connected to an output terminal of the first switch group,
the second switched capacitor filter includes:
a second switch group including an input terminal connected to the first battery cell or the second battery cell; and
a second capacitor connected to an output terminal of the second switch group, and
the first switch group is electrically isolated from the first amplifier via the first capacitor, and the second switch group is electrically isolated from the first amplifier via the second capacitor.

2. The voltage measurement circuit according to claim 1, wherein
the first switched capacitor filter further includes a third switch group connected between the first capacitor and the input terminal of the first amplifier; and
the second switched capacitor filter further includes a fourth switch group connected between the second capacitor and the input terminal of the first amplifier.

3. The voltage measurement circuit according to claim 2, wherein
the first switch group and the second switch group are disposed in a high-voltage region, and
the third switch group, the fourth switch group, and the first amplifier are disposed in a low-voltage region, the low-voltage region being a circuit region in which a circuit that operates with a power supply voltage lower than a power supply voltage in the high-voltage region is disposed.

4. The voltage measurement circuit according to claim 2, further comprising:
a third switched capacitor filter and a fourth switched capacitor filter that are connected between the input terminal and an output terminal of the first amplifier.

5. The voltage measurement circuit according to claim 4, further comprising:
a quantizer connected to a back-side modulator for the first amplifier, wherein
the voltage measurement circuit includes an analog-to-digital converter that converts a voltage of the first battery cell into a digital value, or converts the voltage of the first battery cell and a voltage of the second battery cell into digital values in a time-division manner.

6. The voltage measurement circuit according to claim 5, wherein
the third switch group includes a first digital-to-analog converter that performs digital-to-analog conversion using an output of the quantizer as an input and outputs a resulting analog voltage to an input terminal of the third switch group,
the fourth switch group includes a second digital-to-analog converter that performs digital-to-analog conversion using an output of the quantizer as an input and outputs a resulting analog voltage to an input terminal of the fourth switch group, and
the voltage measurement circuit includes a delta-sigma analog-to-digital converter.

7. The voltage measurement circuit according to claim 5, further comprising, in a path between the first amplifier and the quantizer:
a fifth switched capacitor filter and a sixth switched capacitor filter each including an input terminal connected to an output terminal of the first amplifier;
a second amplifier including an input terminal connected to an output terminal of the fifth switched capacitor filter and connected to an output terminal of the sixth switched capacitor filter; and
a seventh switched capacitor filter and an eighth switched capacitor filter that are connected between the input terminal and an output terminal of the second amplifier, wherein
the voltage measurement circuit includes a second-order or higher delta-sigma analog-to-digital converter.

8. The voltage measurement circuit according to claim 1, wherein the input terminal of the second switched capacitor filter is connected to the second battery cell.

9. A voltage measurement circuit for use in measuring a voltage of each of a plurality of battery cells connected in series and included in a cell pack, the voltage measurement circuit comprising:
a first integrator including an input terminal connected to a battery cell included in the cell pack;
a second integrator including an input terminal connected to an output terminal of the first integrator;
a first amplifier shared by the first integrator and the second integrator;
a quantizer including an input terminal connected at least to an output terminal of the second integrator among the first integrator and the second integrator; and
a first digital-to-analog converter that performs digital-to-analog conversion using an output of the quantizer as an input and outputs a resulting analog voltage to the input terminal of the first integrator, wherein the first integrator and the second integrator each integrate an input signal by sharing the first amplifier in a time-division manner,
the first integrator includes a first switched capacitor filter,
the first switched capacitor filter includes:
a first switch group including an input terminal connected to the battery cell; and
a first capacitor connected to an output terminal of the first switch group, and
the first switch group is electrically isolated from the first amplifier via the first capacitor.

10. The voltage measurement circuit according to claim 1, wherein
the first switched capacitor filter further includes a third switch group connected between the first capacitor and the input terminal of the first amplifier.

11. The voltage measurement circuit according to claim 10, wherein
the first switch group is disposed in a high-voltage region, and
the third switch group and the first amplifier are disposed in a low-voltage region, the low-voltage region being a circuit region in which a circuit that operates with a power supply voltage lower than a power supply voltage in the high-voltage region is disposed.
